(19) United States
(12) Patent Application Publication
(10) Pub. No.: US 2025/0323089 A1
(43) Pub. Date: Oct. 16, 2025

(54) ISOLATION STRUCTURES IN SEMICONDUCTOR DEVICES

(71) Applicant: Yangtze Memory Technologies Co., Ltd., Wuhan (CN)

(72) Inventors: Shuangshuang WU, Wuhan (CN); Linchun WU, Wuhan (CN); Di WANG, Wuhan (CN); Kun ZHANG, Wuhan (CN); Wenxi ZHOU, Wuhan (CN); Zhiliang XIA, Wuhan (CN)

(21) Appl. No.: 18/784,843

(22) Filed: Jul. 25, 2024

Related U.S. Application Data
(63) Continuation of application No. PCT/CN2024/087434, filed on Apr. 12, 2024.

(51) Int. Cl. H01L 21/762; G11C 16/04; H01L 23/532; H10B 41/10; H10B 41/27; H10B 41/35; H10B 43/10; H10B 43/27; H10B 43/35

(52) U.S. Cl. CPC H01L 21/76224; G11C 16/0483; H01L 23/53295; H10B 41/10; H10B 41/27; H10B 41/35; H10B 43/10; H10B 43/27; H10B 43/35

(57) ABSTRACT

The present disclosure relates to methods, devices, systems, and techniques for managing isolation structures in semiconductor devices. An example semiconductor device includes an array region, a connection region, and a stack of conductive layers and insulating layers alternating with each other along a first direction. The semiconductor device further includes a gate line structure having at least a first segment and a second segment. The gate line structure extends along a second direction perpendicular to the first direction. The semiconductor device further includes an isolation structure separating the first segment from the second segment. A size of the isolation structure in a third direction is same as a size of the first segment in the third direction. The third direction is perpendicular to the first direction and the second direction.

### CROSS-REFERENCE TO RELATED APPLICATIONS

This application is a continuation of International Application No. PCT/CN2024/087434, filed on Apr. 12, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing isolation structures in semiconductor devices.

One aspect of the present disclosure features a semiconductor device. The semiconductor device includes an array region, a connection region, a stack of conductive layers and insulating layers alternating with each other along a first direction, a gate line structure including at least a first segment and a second segment, and an isolation structure separating the first segment from the second segment. The gate line structure extends along a second direction perpendicular to the first direction. A size of the isolation structure in a third direction is same as a size of the first segment in the third direction. The third direction is perpendicular to the first direction and the second direction.

In some implementations, a size of the isolation structure in the second direction is smaller than a size of the first segment in the second direction, the size of the isolation structure in the third direction is the same as a size of the second segment in the third direction.

In some implementations, the isolation structure extends through the stack along the first direction, the isolation structure is between dummy channel structures along the third direction, a part of at least one insulating layer of the stack separates the isolation structure and the dummy channel structures from each other along the third direction, the gate line structure extends through the stack along the first direction, and the gate line structure extends into the array region and the connection region along the second direction.

In some implementations, the isolation structure includes a first sidewall in contact with the first segment and a second sidewall in contact with the second segment, and the first sidewall and the second sidewall each have a concave surface extending along the first direction. The isolation structure includes a third sidewall and a fourth sidewall in contact with the stack along the third direction. The third sidewall and the fourth sidewall each include a series of curved portions.

In some implementations, a bottom of the isolation structure includes a series of bases arranged in a line along the second direction, a size of a first cross section of each base of the series of bases is greater than a size of a second cross section of the base, the first cross section and the second cross section are perpendicular to the first direction, and the first cross section is closer to the stack than the second cross section along the first direction.

In some implementations, the first segment is in the array region, the second segment and the isolation structure are in the connection region.

In some implementations, the first segment, the second segment, and the isolation structure are in the array region.

In some implementations, the isolation structure includes a dielectric material.

In some implementations, the isolation structure includes an inner structure and an outer layer surrounding the inner structure, and the inner structure and the outer layer include different materials.

Another aspect of the present disclosure features a method including providing a semiconductor structure including a substrate and a stack of sacrificial layers and insulating layers alternating with each other along a first direction. The method further includes forming gate line holes and channel holes by a same etching process, where the gate line holes and the channel holes extend through the stack and into the substrate along the first direction, the gate line holes are arranged in a line along a second direction perpendicular to the first direction, and the gate line holes include a first group of gate line holes. The method further includes forming an isolation trench by expanding the first group of gate line holes. The method further includes forming a first isolation structure by filling at least one isolating material into the isolation trench.

In some implementations, the gate line holes further include a second group of gate line holes and a third group of gate line holes, the first group of gate line holes are between the second group of gate line holes and the third group of gate line holes, and the first group of gate line holes are adjacent to the second group of gate line holes and the third group of gate line holes.

In some implementations, the isolation trench includes expanded gate line holes formed from the first group of gate line holes, and the expanded gate line holes are connected with each other along the second direction.

In some implementations, the first isolation structure includes a solid dielectric structure, and forming the first isolation structure includes filling a dielectric material into the isolation trench.

In some implementations, the first isolation structure includes an inner structure and an outer layer surrounding the inner structure, and forming the first isolation structure includes forming the outer layer by depositing a dielectric material on a bottom and an inner surface of the isolation trench and forming the inner structure by filling a filler material into the isolation trench.

In some implementations, the method further includes forming channel structures in the channel holes, filling the gate line holes with polysilicon, and removing the polysilicon in the second group of gate line holes and the third group of gate line holes.

In some implementations, the method further includes forming a first segment of a gate line trench, a second segment of the gate line trench, and a second isolation structure by expanding the second group of gate line holes and the third group of gate line holes.

In some implementations, the first segment of the gate line trench includes expanded gate line holes that are formed from the second group of gate line holes and are connected with each other along the second direction, the second segment of the gate line trench includes expanded gate line holes that are formed from the third group of gate line holes and are connected with each other along the second direction, the second isolation structure is formed by removing a first end of the first isolation structure and a second end of the first isolation structure. The first end overlaps with the first segment of the gate line trench, and the second end overlaps with the second segment of the gate line trench.

In some implementations, the first segment of the gate line trench is in an array region of the semiconductor structure, and the second isolation structure and the second segment of the gate line trench are in a connection region of the semiconductor structure.

In some implementations, the method further includes forming a recess space in the connection region by filling an etchant into the second segment of the gate line trench to recess the sacrificial layers in the connection region, filling the second segment of the gate line trench and the recess space with carbon, removing the sacrificial layers in the array region by filling the etchant into the first segment of the gate line trench, removing the carbon in the connection region, and forming conductive layers between the insulating layers by depositing at least a conductive material through the first segment of the gate line trench.

A further aspect of the present disclosure features a memory system. The memory system includes a memory device and a memory controller coupled to the memory device and configured to control the memory device. The memory device includes an array region, a connection region, a stack of conductive layers and insulating layers alternating with each other along a first direction, a gate line structure including at least a first segment and a second segment, and an isolation structure separating the first segment from the second segment. The gate line structure extends along a second direction perpendicular to the first direction. A size of the isolation structure in a third direction is same as a size of the first segment in the third direction. The third direction is perpendicular to the first direction and the second direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIGS. 1A-1D illustrate an example semiconductor device.

FIGS. 2A-2R illustrate an example process of manufacturing a semiconductor device.

FIG. 3 illustrates a flow chart of an example process of manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher-density, a memory device (e.g., a 3D NAND flash memory) can be formed to have multiple decks, and each deck can have a large number of layers. The large number of layers and the high aspect ratio of such memory device may bring challenges to the manufacturing process. For example, stress issues can become more severe and cause X-Y bow problem in conductive layer filling. In another example, components with high aspect ratios in the memory device (e.g., gate line structures and memory blocks) may tilt, shift, or even collapse during the manufacturing process. Furthermore, the increase in depth of the memory device may introduce or exacerbate overlay (OVL) issues in the manufacturing process. In some implementations, channel holes and gate line holes can be formed in a same etching process using a same etching mask. The gate line holes can be expanded and form a gate line trench (also referred to as a gate line slit). This process can be referred to as channel hole and gate line hole merging and can enlarge the process window in the manufacturing process and can mitigate or resolve the OVL issue. In some implementations, isolation structures can be formed to separate the gate line structure into multiple segments, thereby releasing stress in the gate line structure. The isolation structures also can divide the gate line trench into multiple segments and allow the conductive layer filling to be performed in separate processes, thereby improving the quality and reliability of the conductive layers. Therefore, isolation structures that are compatible with the channel hole and gate line hole merging and can solve the aforementioned issues are desirable.

In one or more implementations of the present disclosure, an example semiconductor device is provided. The semiconductor device includes an array region, a connection region, and a stack of conductive layers and insulating layers alternating with each other along a first direction. The semiconductor device includes a gate line structure having at least a first segment and a second segment. The semiconductor device further includes an isolation structure separating the first segment from the second segment. A cross section of the isolation structure has a shape of connected partial circles. The cross section is perpendicular to the first direction.

Implementations of the present disclosure can provide one or more of the following technical advantages and/or benefits. The isolation structure can avoid occupying space in the array region for channel structures, thereby increasing storage density and capacity of a memory device. In addition, the fabrication process of the isolation structure can avoid affecting electrical functionalities of surrounding channel structures. The isolation structure provides isolation by forming sidewalls in contact with adjacent structures rather than removing dielectric materials in the adjacent structures, thereby avoiding seams (which may cause an isolation failure) formed during the latter process. The isolation structure can allow the sacrificial layer removing processes in the array region and the connection region to be separated, thereby improving the product yield and the structural stability, and reducing the fabrication costs.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

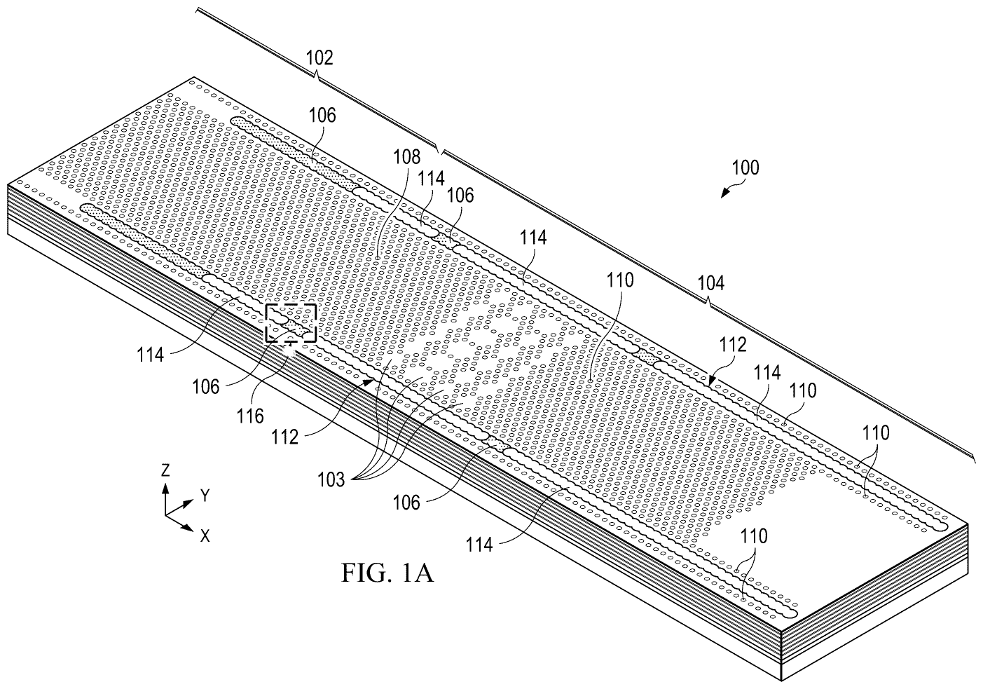

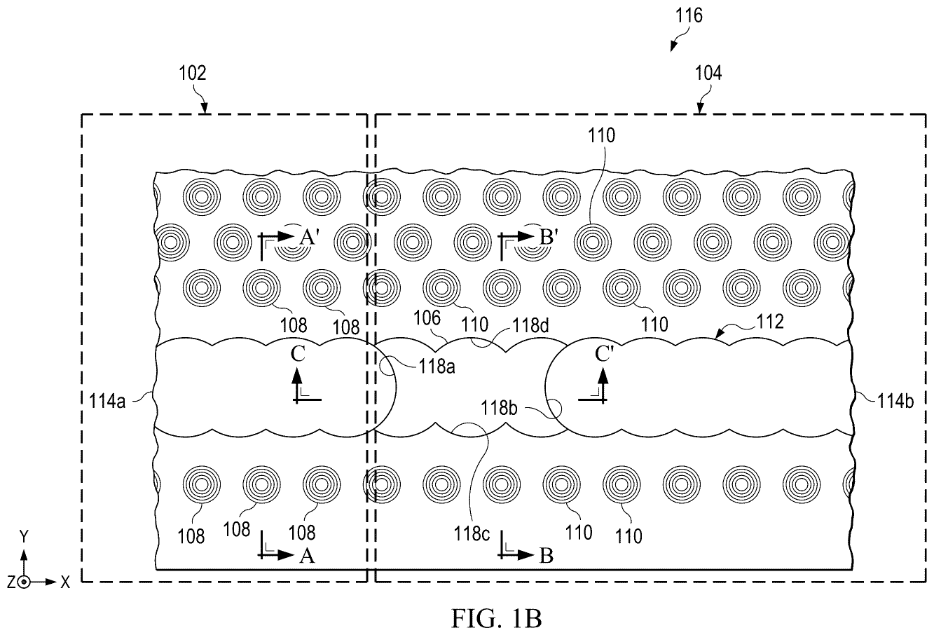

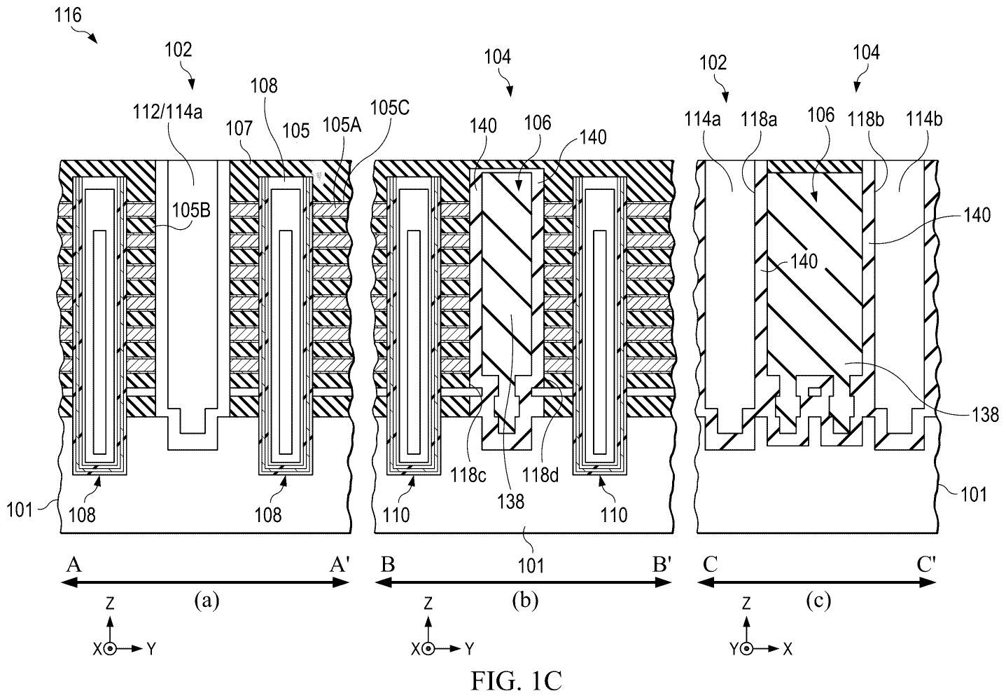

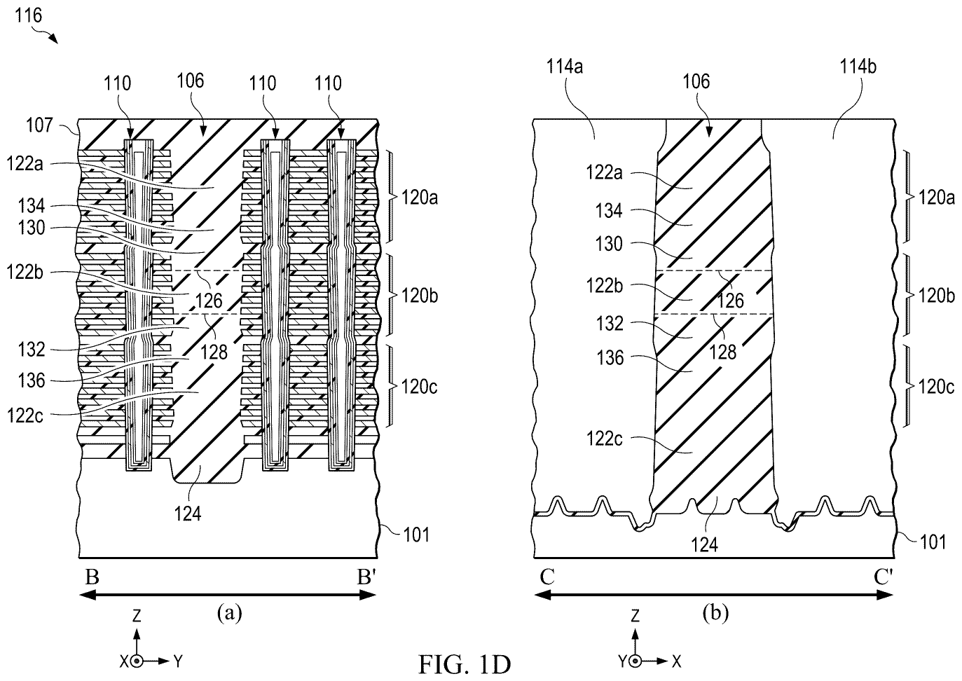

It is noted that X, Y, and Z axes (also referred to as X, Y, and Z directions) are included in FIGS. 1A-1D to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a perspective view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). In some implementations, an array of channel structures 108 can be in the array region 102. Each channel structure 108 can be used to form a string of memory cells coupled in serial along a vertical direction (e.g., Z direction) perpendicular to the first horizontal direction. In some implementations, a staircase structure (not shown) and an array of contact structures (not shown) formed on the staircase structure can be in the connection region 104. In some other implementations, conductive layers (e.g., conductive layers 105A in FIG. 1C as described below) in the connection region 104 can form a structure different from a staircase structure. For example, a contact structure can be connected to a corresponding conductive layer and can extend through other conductive layers, and spacer for insulation can be formed between the contact structure and the other conductive layers. In some implementations, the semiconductor device 100 can include dummy channel structures 110 (also referred to as dummy memory strings) for process variation control during fabrication and/or for additional mechanical support. In some implementations, the dummy channel structures 110 are in the connection region 104. For example, some dummy channel structures 110 can be in an edge or peripheral area of the connection region 104. In some instances, the edge area of the connection region 104 is adjacent to the array region 102. In some other instances, the edge area of the connection region 104 is adjacent to a gate line structure (e.g., gate line structure 112 as shown in FIG. 1A). In some implementations, the dummy channel structures 110 are in the array region 102 (e.g., an area adjacent to the connection region 104). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

In some implementations, an array of sub-regions 103 can be in the connection region 104. In some instances, trough array contacts (TACs), which are not shown in FIG. 1A, can be formed in the sub-regions 103. The TACs can extend through a stack of alternating conductive layers and insulating layers (e.g., the stack 105 of FIG. 1C) and connect components on opposite sides of the stack (e.g., along the vertical direction). Dummy channel structures 110 can be located outside of the sub-regions 103 and can surround the sub-regions 103 laterally.

The semiconductor device 100 can include one or more gate line structures 112. Each gate line structure 112 can extend in the X direction. The gate line structure 112 can extend into both the array region 102 and the connection region 104. In some implementations, the gate line structures 112 can divide an array region into multiple memory blocks. In some implementations, the gate line structure 112 can function as a common source contact for the channel structures 108 in the array region 102. As shown in FIG. 1A, each gate line structure 112 can include multiple segments 114 extending along the X direction. The segments 114 can be separated and spaced by isolation structures 106 along the X direction. The isolation structures 106 can eliminate or reduce stress built in the gate line structure 112 during the manufacturing process, thereby preventing the gate line structure 112 from bending or cracking. In some implementations, as shown in FIGS. 1A-1B, the isolation structure 106 is in the connection region 104 and is adjacent to the array region 102. In some other implementations, the isolation structure 106 is in the array region 102 and is adjacent to the connection region 104. In some other implementations, the isolation structure 106 can have a portion in the array region 102 and another portion in the connection region 104. In some implementations (not shown in FIG. 1A), the gate line structure 112 can further include one or more segments 114 extending along a second horizontal direction (e.g., the Y direction). In some implementations, the gate line structure 112 can include multiple segments 114 connected in an H shape or a T shape.

FIG. 1B illustrates an example of a portion 116 of the semiconductor device 100. FIG. 1B provides a top view (also an enlarged view) of the portion 116, which includes the isolation structure 106 and structures adjacent to the isolation structure 106. The isolation structure 106 separates a segment 114a of the gate line structure 112 from a segment 114b of the gate line structure 112. The isolation structure 106 can be in any suitable position in the gate line structure 112 along the X direction. In this example, the isolation structure 106 and the segment 114b are in the connection region 104, and the segment 114a is in the array region 102. In some other examples (as shown in FIG. 1A), the isolation structure 106 can be in the array region 102 and can be between two segments 114. One of the two segments 114 adjacent to the isolation structure 106 can be in the array region 102. Another of the two segments 114 can be in the array region 102, or the other segment 114 can have a portion in the array region 102 and another portion in the connection region 104. As shown in FIG. 1B, a cross section of the isolation structure 106 can be in a shape of connected partial circles. The cross section of the isolation structure 106 is in the X-Y plane and is perpendicular to the Z direction. In some implementations, the isolation structure 106 includes two sidewalls 118a and 118b opposite to one another along the X direction. The sidewall 118a can be in contact with the segment 114a, and the sidewall 118b can be in contact with the segment 114b. The sidewalls 118a and 118b each can have a concave surface (e.g., as shown in FIG. 1B) extending along the Z direction (e.g., as shown in FIG. 1C (c)). For example, the concave surface curves inwards from the segment 114a or 114b towards the isolation structure 106. The isolation structure 106 further includes two sidewalls 118c and 118d opposite to one another along the Y direction. The sidewalls 118c and 118d extend along the Z direction and are in contact with the stack 105 (e.g., as shown in FIG. 1C (b)). Each of the sidewalls 118c and 118d can be non-flat and can include a series of curved portions connected together (e.g., along the X direction). For example, the series of curved portions can be wave-like or caterpillar-like. In some implementations, a size of the isolation structure 106 in the X direction is smaller than a size of the segment 114a in the X direction and a size of the segment 114b in the X direction. In some implementations, a size of the isolation structure 106 in the Y direction is similar to, or the same as, a size of the segment 114a in the Y direction and a size of the segment 114b in the Y direction.

FIGS. 1C (a)-(c) illustrate cross-sectional views of the portion 116 of the semiconductor device 100 along cut lines AA′, BB′, and CC′ of FIG. 1B, respectively. In some implementations, as illustrated in FIGS. 1C (a) and 1C (b), the semiconductor device 100 includes a substrate 101 and a stack 105 of alternating conductive layers 105A and insulating layers 105B provided over the substrate 101. In some implementations, the substrate 101 can be removed from the semiconductor device 100 in a later process. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. The semiconductor device 100 can include a top layer 107 made of an isolating material (e.g., oxide).

The stack 105 can extend in the second horizontal direction (e.g., the Y direction) that is parallel to a top surface of the substrate 101 and perpendicular to the first horizontal direction (e.g., the X direction). The conductive layers 105A and the insulating layers 105B can alternate in the vertical direction (e.g., Z direction) perpendicular to the second horizontal direction. The conductive layers 105A can be the same or different from each other in thickness, for example, ranging from 10-500 nm, e.g., about 35 nm. The insulating layers 105B can also be the same or different from each other in thickness, for example, ranging from 10-500 nm, e.g., about 25 nm. It should be noted that the number of the conductive layers 105A and the insulating layers 105B shown in FIG. 1C (a) or 1C (b) is for illustration only and that any suitable number of the conductive layers 105A and the insulating layers 105B can be included in the stack 105. The conductive layers 105A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The insulating layers 105B can include a dielectric material, such as silicon oxide, silicon nitride, silicon oxynitride, or any combination thereof. In some implementations, the insulating layers 105B can also include high-K dielectric materials, such as hafnium oxide, zirconium oxide, aluminum oxide, tantalum oxide, lanthanum oxide, or any combination thereof.

In some implementations, as illustrated in FIG. 1C (a) or FIG. 1C (b), the stack 105 includes liner layers 105C. A liner layer 105C can cover part or all sides of a corresponding conductive layer 105A and be between the conductive layer 105A and two insulating layers 105B adjacent to the corresponding conductive layer 105A. The liner layer 105C can include a high-K dielectric material (e.g., Al₂O₃). In some examples, the conductive layer 105A includes a metallic material (e.g., W) and an adhesive material (e.g., TiN), and the adhesive material can be deposited between the metallic material and the high-K dielectric material. In some examples, the conductive layer 105A includes the metallic material (e.g., W), and the liner layer 105C includes the adhesive material (e.g., TiN) and the high-K dielectric material.

In some implementations, as shown in FIG. 1C, the channel structures 108 and the dummy channel structures 110 can extend through the stack 105 along the vertical direction (e.g., the Z direction). The gate line structure 112 also can extend through the stack 105 along the vertical direction (e.g., the Z direction). The dummy channel structure 110 and the channel structure 108 can have similar or the same structure and can be formed in the same manufacturing process. Each channel structure 108 (or dummy channel structure 110) can be in the shape of a cylinder or a pillar, and can include a high-K layer, a block layer surrounded by the high-K layer, a charge trapping layer (or a storage layer) surrounded by the block layer, a tunneling layer surrounded by the charge trapping layer, a channel layer surrounded by the tunneling layer, and a core filler layer surrounded by the channel layer, which extend through the conductive layers 105A and the insulating layers 105B of the stack 105, and a channel contact formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-k dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide).

As shown in FIG. 1C (b), the isolation structure 106 can extend through the stack 105 along the Z direction. In some implementations, the isolation structure 106 can be between the dummy channel structures 110 along the Y direction. The isolation structure 106 may not be in contact with the dummy channel structures 110. That is, at least a part of each conductive layer 105A and each insulating layer 105B in the stack 105 can separate the isolation structure 106 and the dummy channel structures 110 from each other along the Y direction.

In some implementations, as shown in FIG. 1D, the stack 105 can include multiple decks (e.g., decks 120a, 120b, and 120c) stacked along the vertical direction (e.g., the Z direction). Each of the multiple decks can include a subset of the conductive layers 105A and the insulating layers 105B in the stack 105. The isolation structure 106 can have multiple body portions (e.g., 122a, 122b, and 122c) and a bottom portion (e.g., 124) sequentially connected along the vertical direction. Each body portion can be in a respective deck of the stack 105, and the bottom portion 124 can extend beyond the stack 105. The bottom portion 124 can include a series of bases arranged in a line along the X direction. Each base can be in a shape of a truncated cone. In some implementations, a size of a first cross section of the base is greater than a size of a second cross section of the base. The first cross section and the second cross section are perpendicular to the Z direction. The first cross section is closer to the stack 105 than the second cross section (e.g., along the Z direction).

As shown in FIG. 1D (a), along the Y direction, each of the body portions 122a, 122b, and 122c of the isolation structure 106 can have a size gradually reducing along the vertical direction (e.g., the Z direction). For example, the body portion 122b has a cross section 126 and a cross section 128 both perpendicular to the vertical direction. The cross section 126 is closer to the top layer 107 than the cross section 128 along the vertical direction. A size of the cross section 126 along the Y direction is larger than a size of the cross section 128 along the Y direction. The body portion 122b has a top end 130 and a bottom end 132 opposite to each other along the Z direction. The top end 130 is closer to the top layer 107 than the bottom end 132 along the vertical direction. The top end 130 of the body portion 122b is connected to a bottom end 134 of the body portion 122a. A size of a cross section of the top end 130 along the Y direction is larger than a size of a cross section of the bottom end 134 along the Y direction. The bottom end 132 of the body portion 122b is connected to a top end 136 of the body portion 122c. A size of a cross section of the bottom end 132 along the Y direction is smaller than a size of a cross section of the top end 136 along the Y direction. As shown in FIG. 1D (a), the dummy channel structures 110 can also have multiple portions, which have structures similar to the body portions 122a, 122b, and 122c of the isolation structure 106 along the Y direction, as described above.

As shown in FIG. 1D (b), a size of the cross section 126 along the X direction is smaller than a size of the cross section 128 along the X direction. A size of the cross section of the top end 130 along the X direction is smaller than a size of the cross section of the bottom end 134 along the X direction. A size of the cross section of the bottom end 132 along the X direction is larger than a size of the cross section of the top end 136 along the X direction.

In some implementations, as shown in FIGS. 1D (a) and 1D (b), the isolation structure 106 can be a solid structure made of a dielectric material (e.g., silicon oxide). In some implementations, as shown in FIGS. 1C (b) and 1C (c), the isolation structure 106 can include an inner structure 138 and an outer layer 140 surrounding the inner structure 138. The inner structure 138 and the outer layer 140 can include different materials. For example, the inner structure 138 can include a semiconductor material such as polysilicon, and the outer layer 140 can include a dielectric material such as silicon oxide.

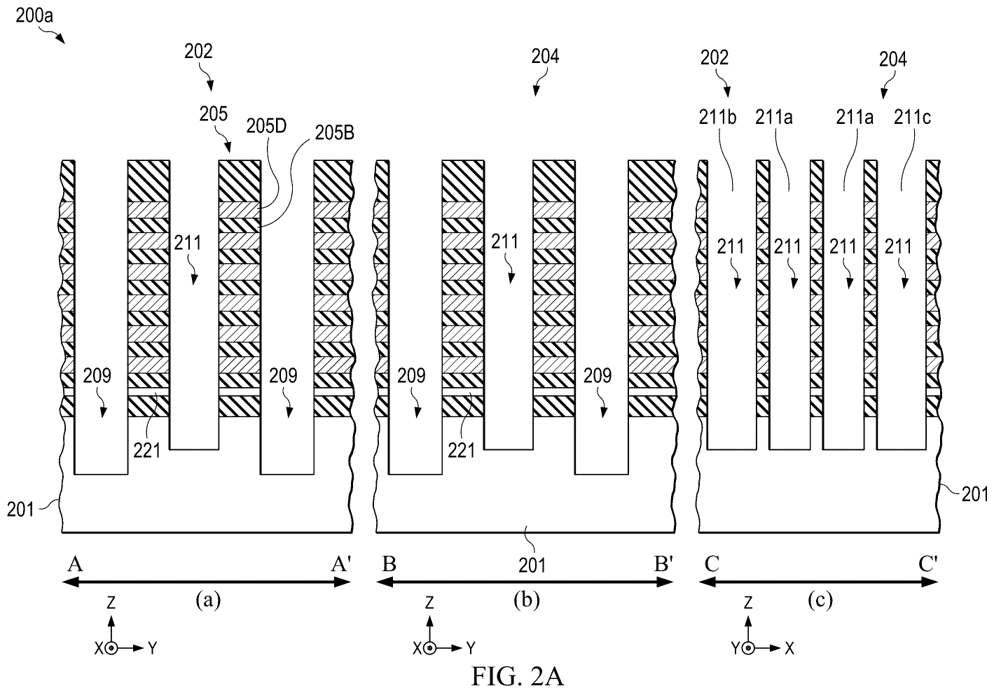

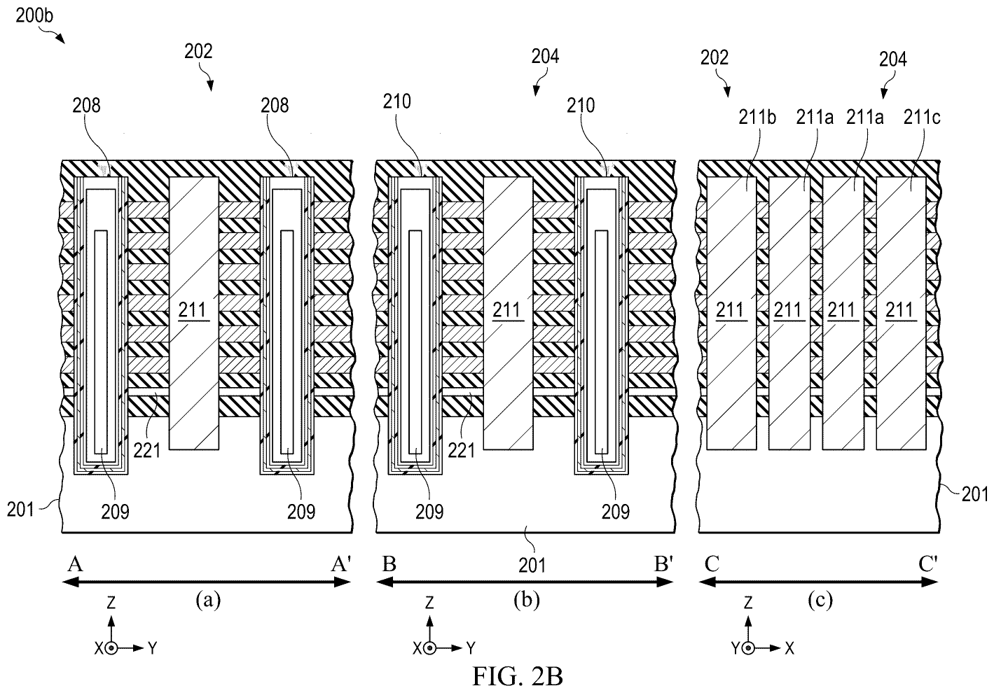

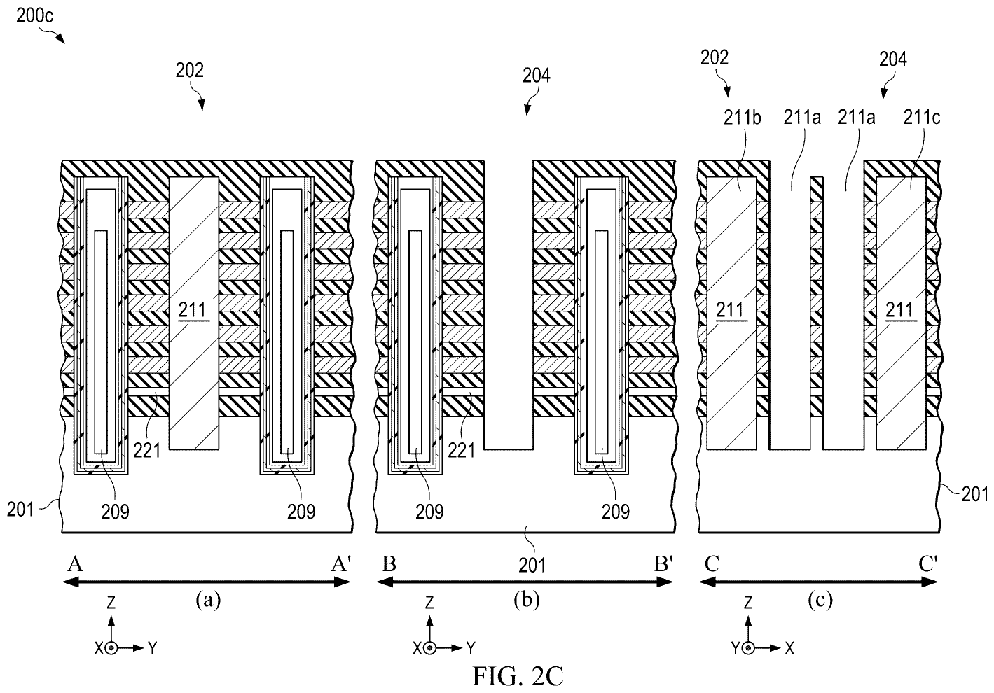

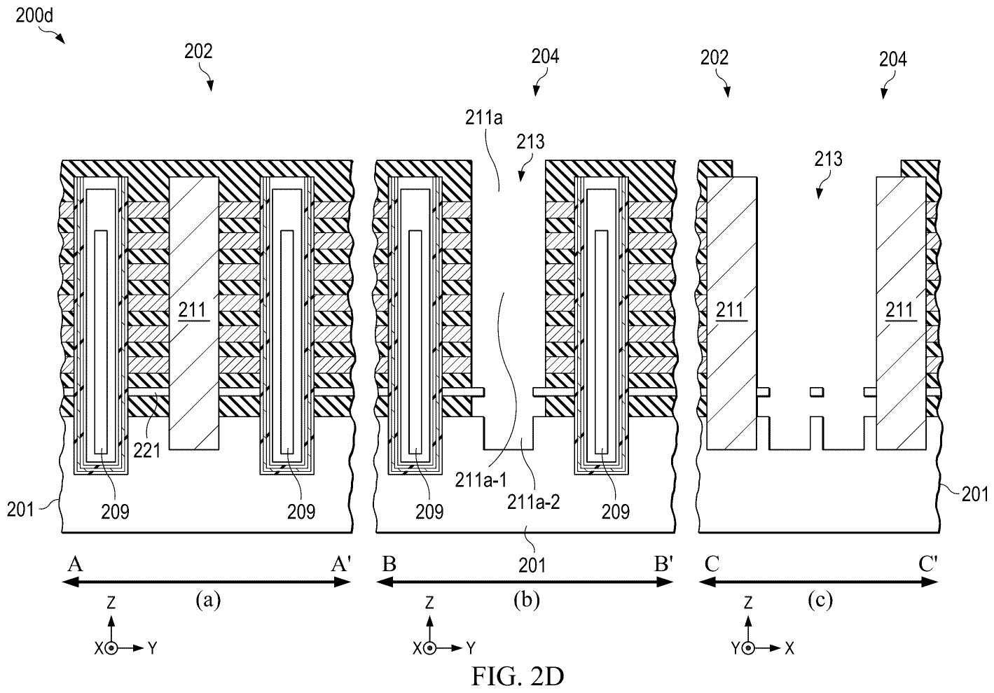

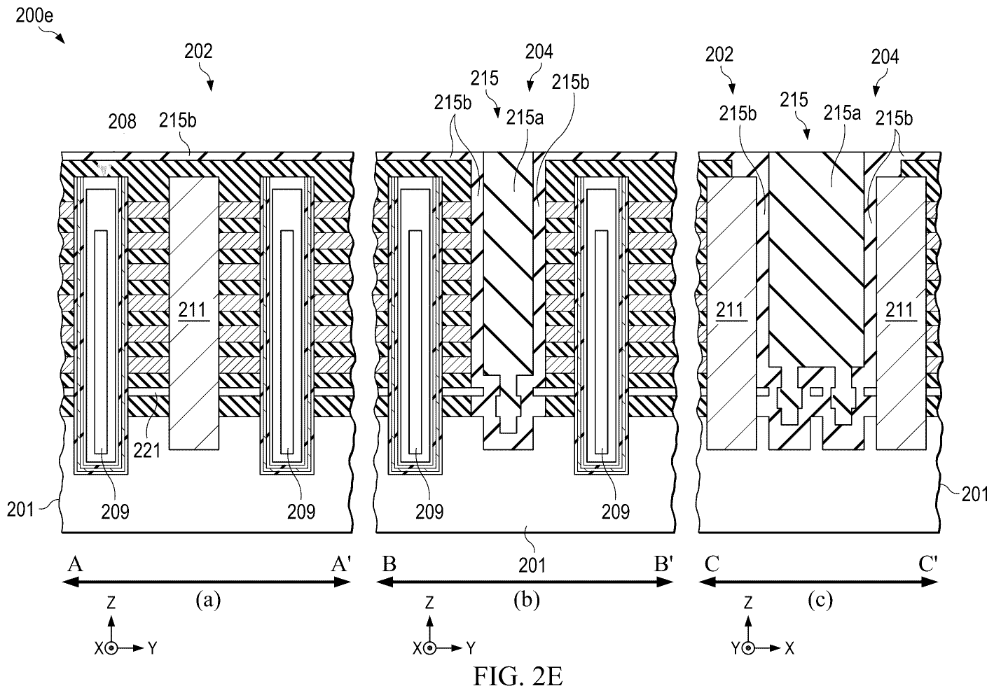

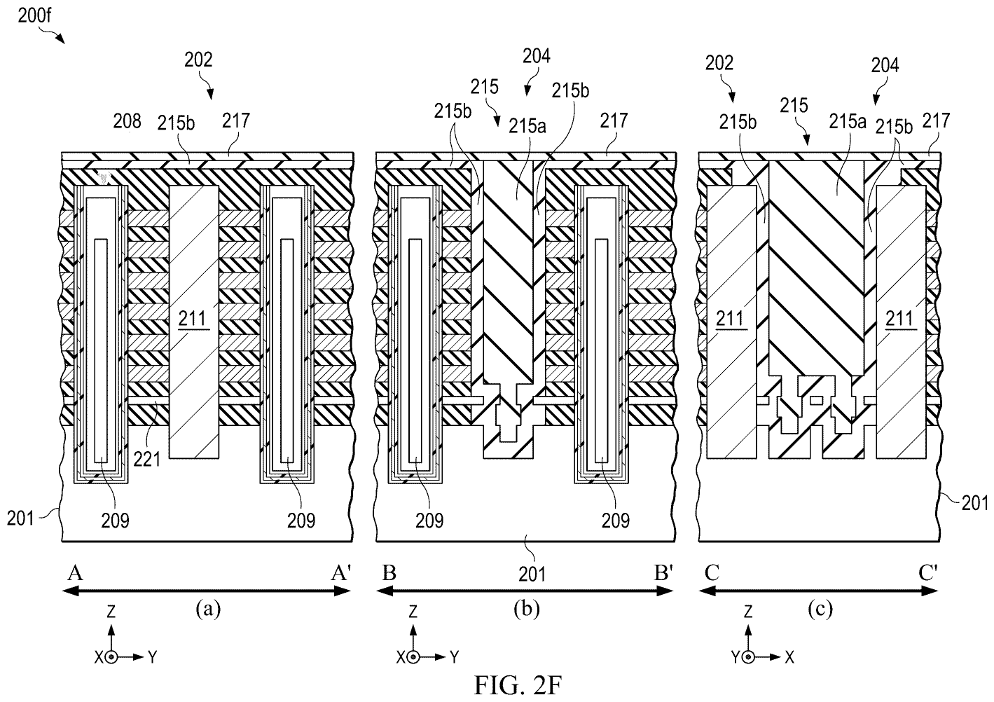

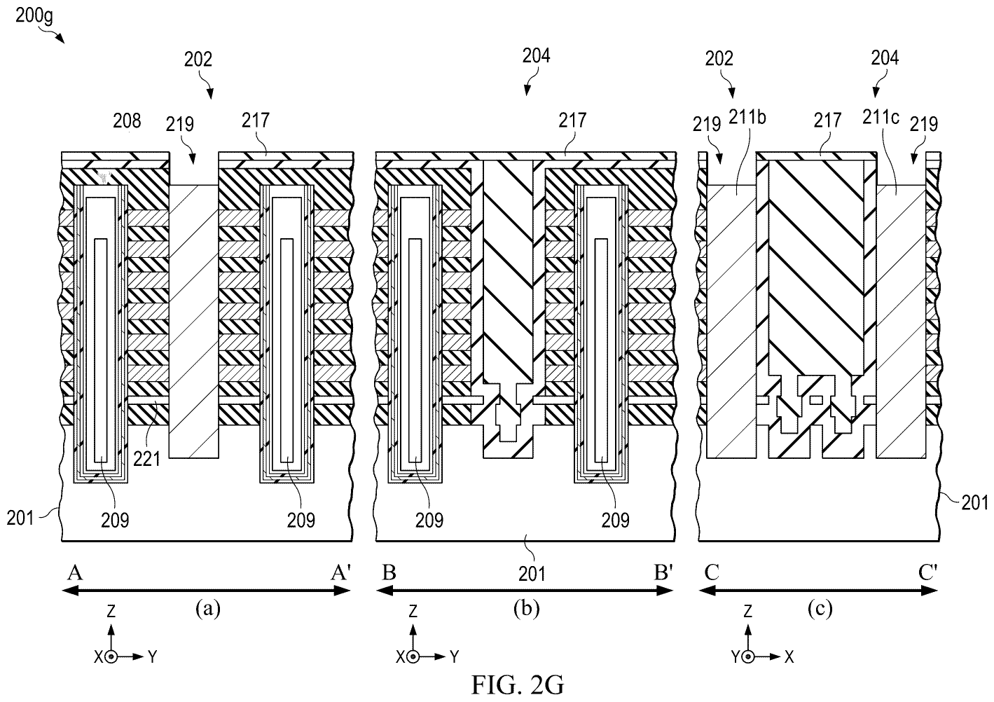

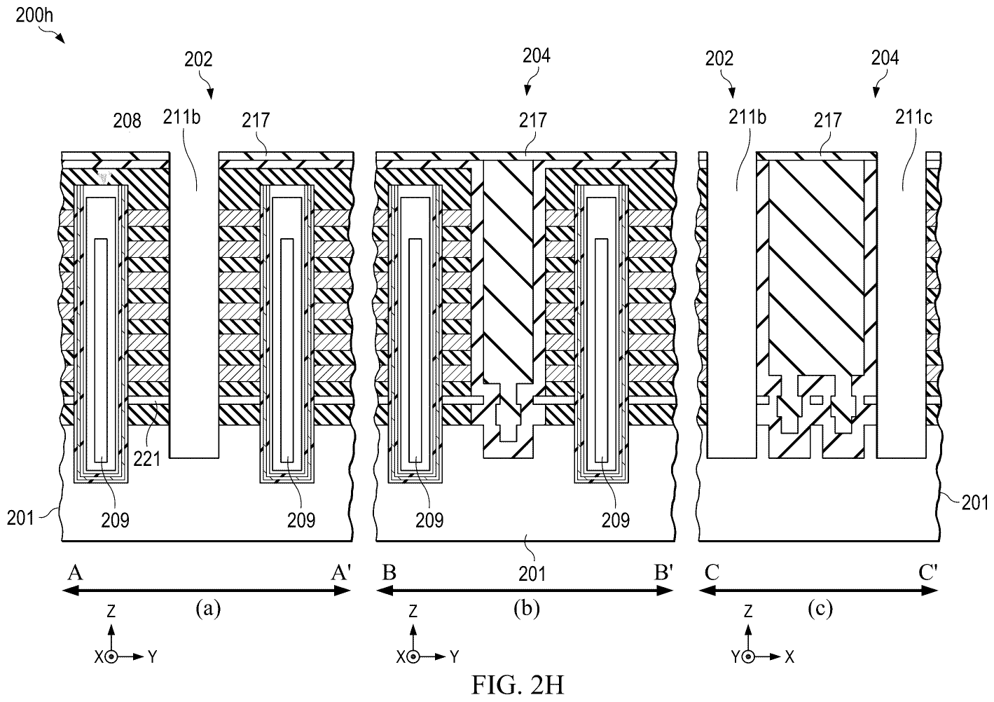

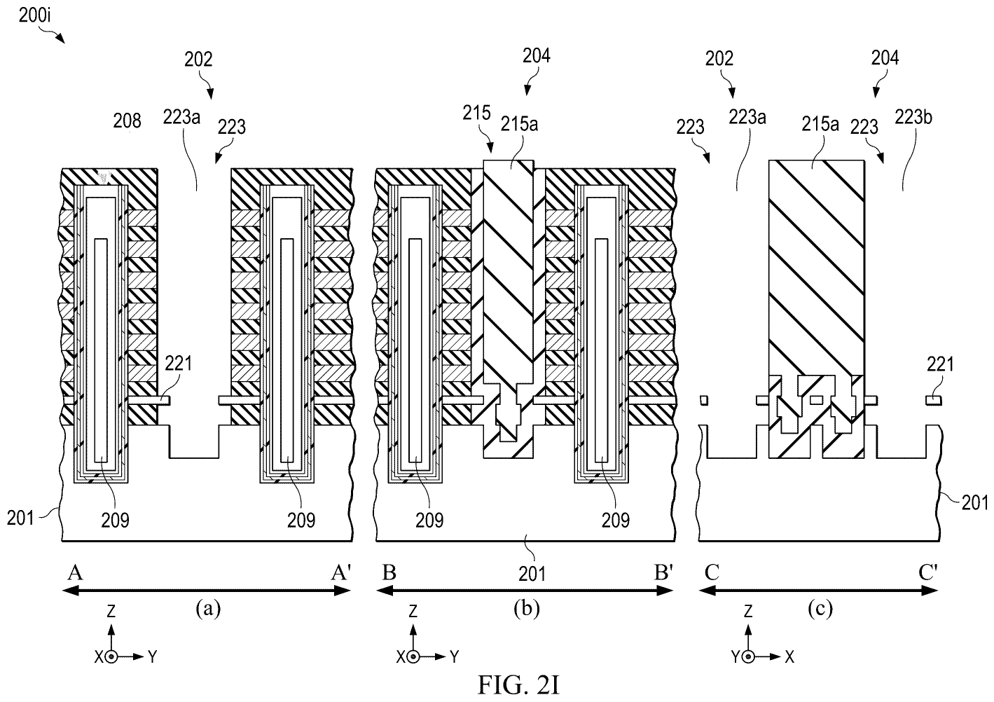

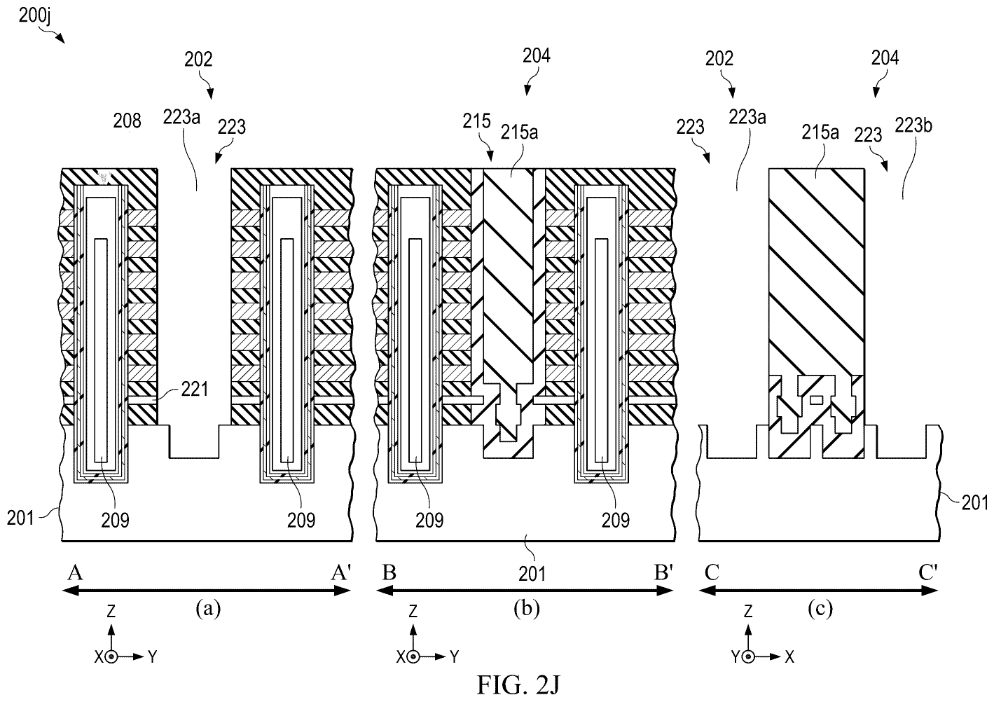

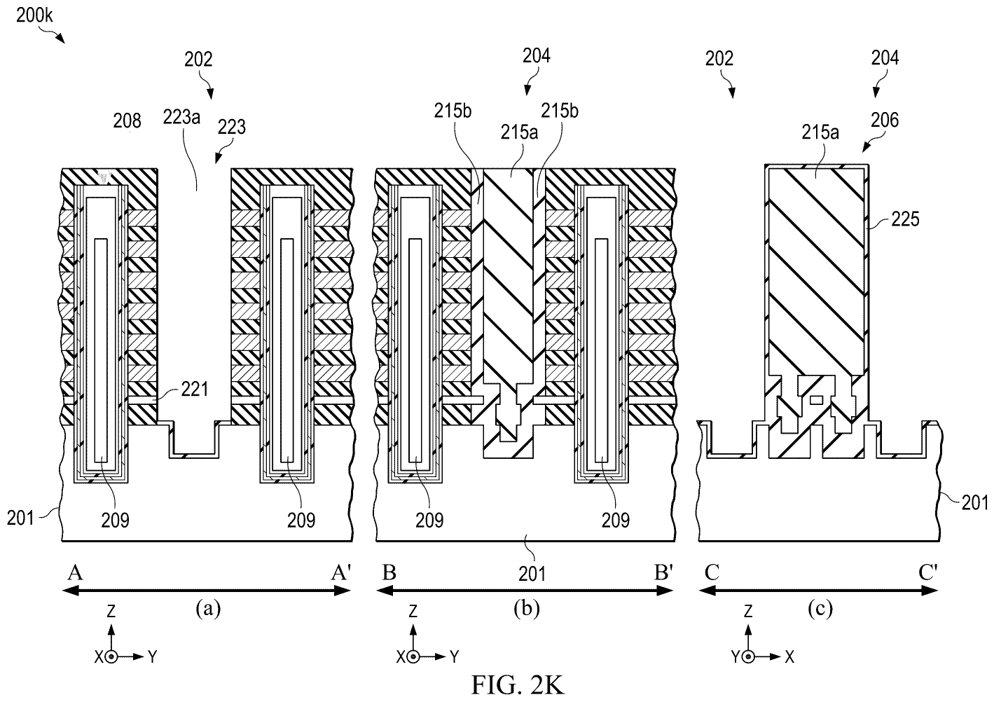

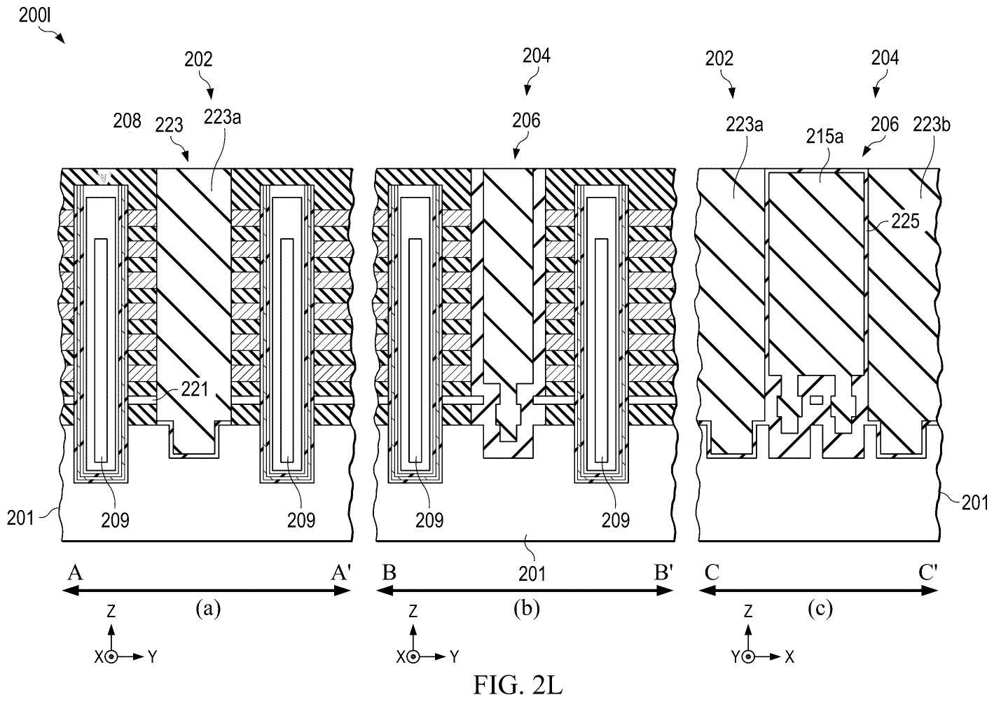

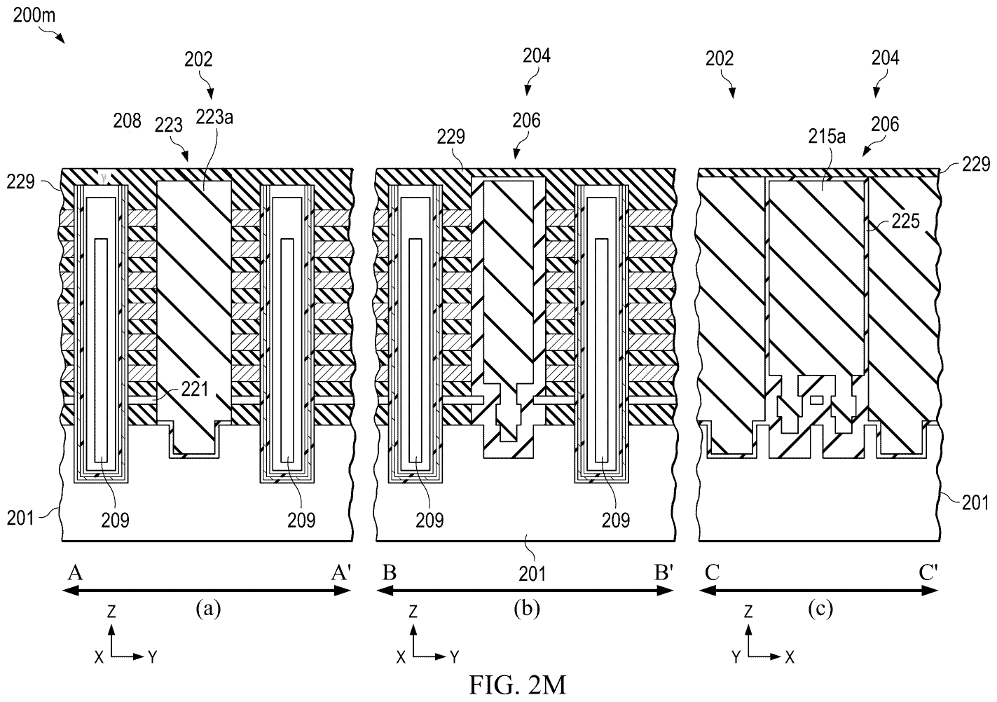

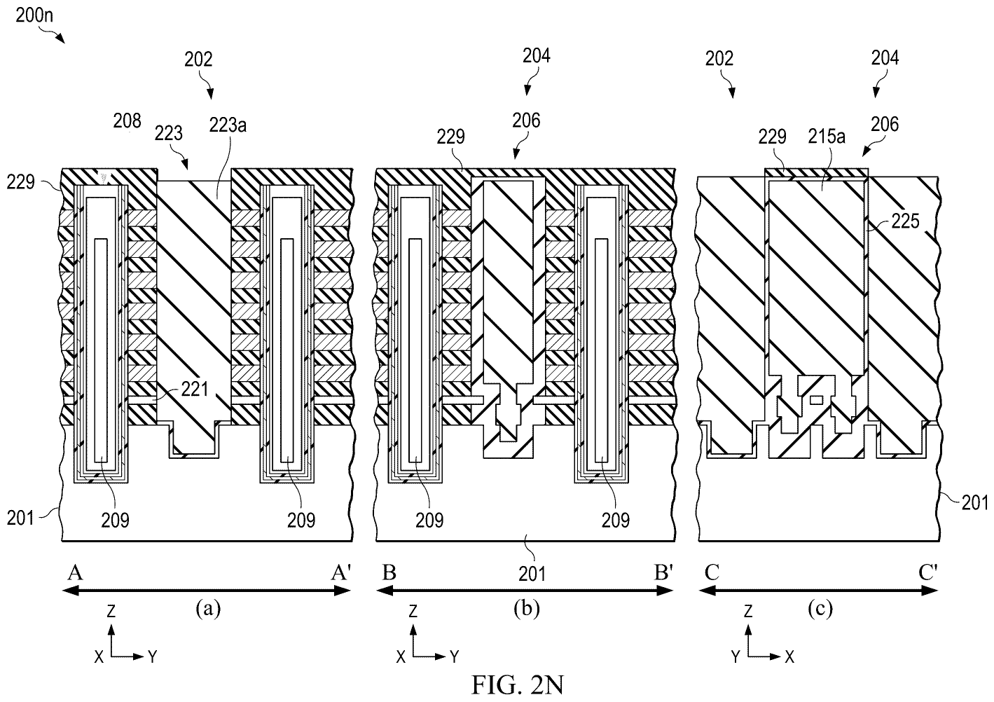

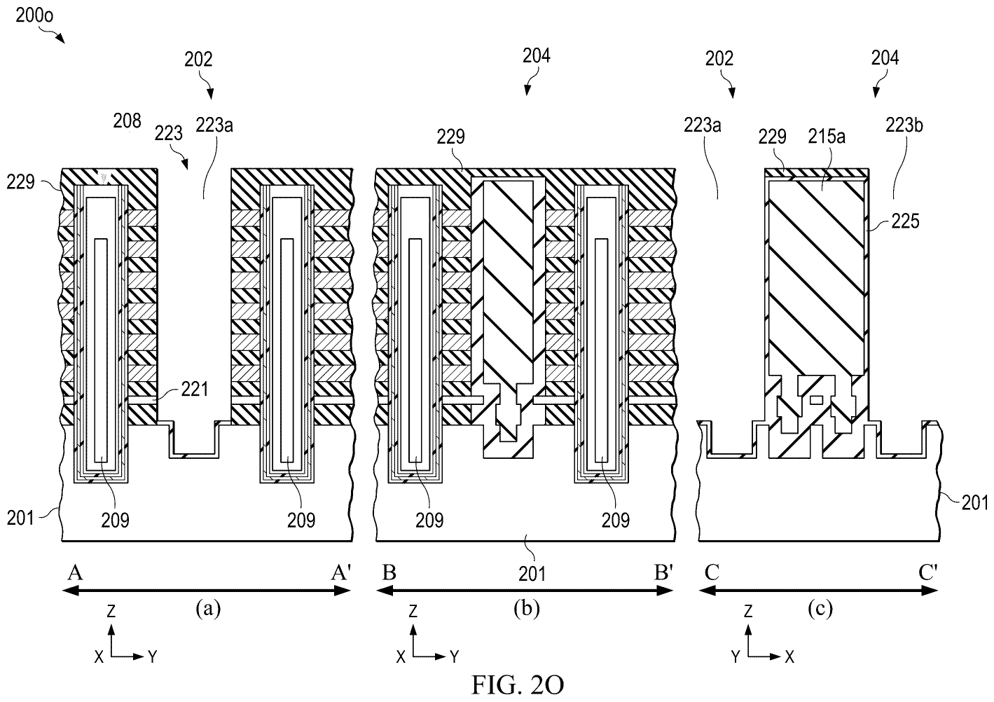

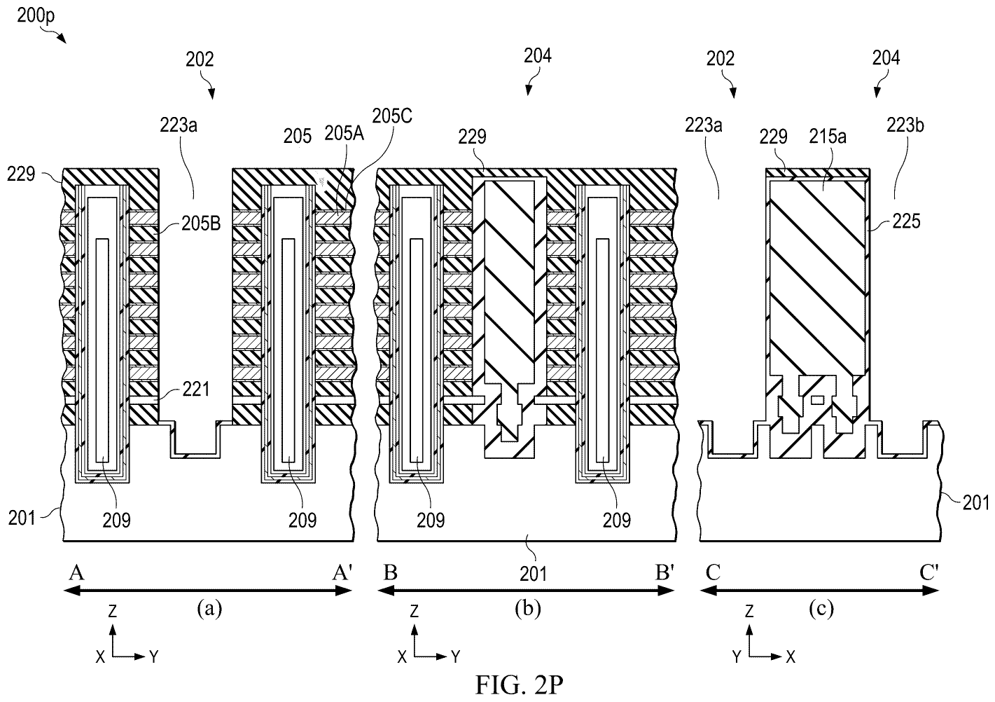

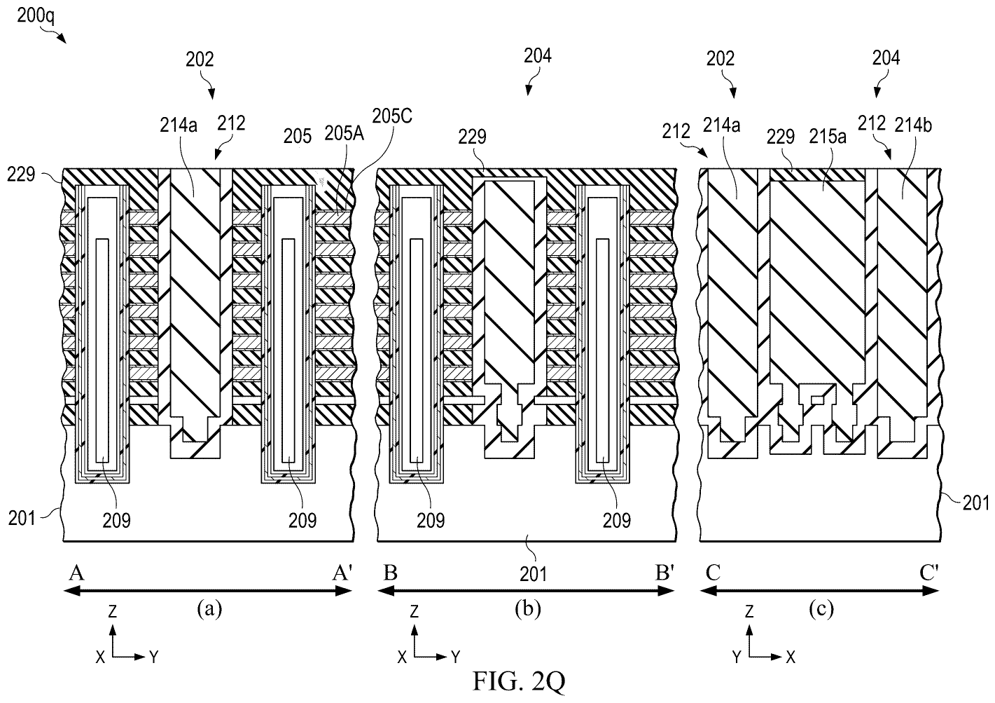

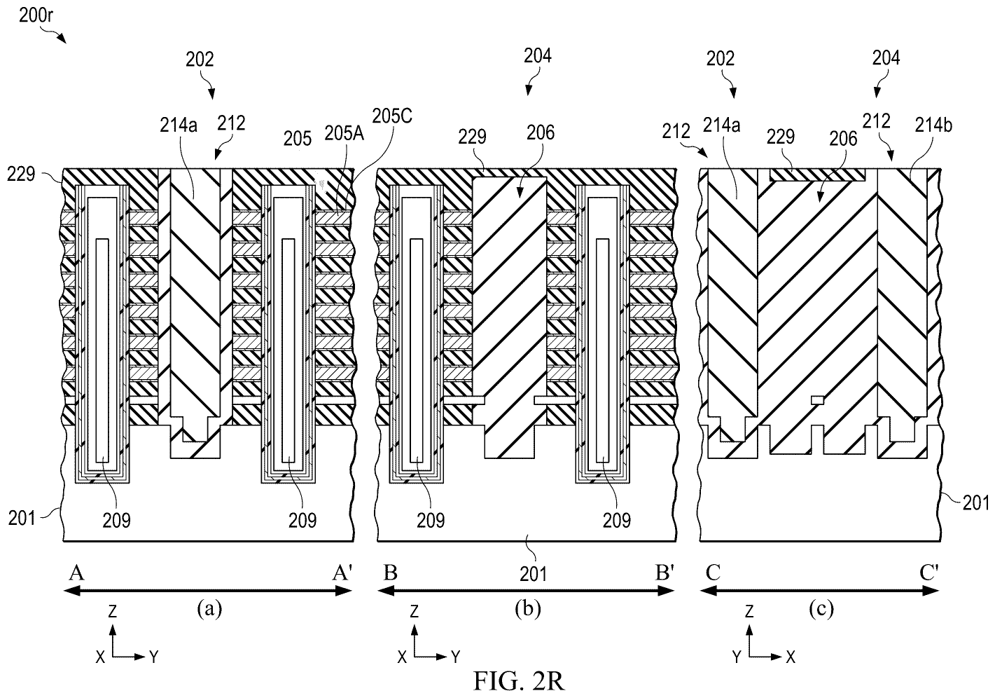

FIGS. 2A-2R illustrate an example process of fabricating a semiconductor device, such as the semiconductor device 100 as illustrated in FIGS. 1A-1D. FIGS. 2A-2R show cross-sectional views of example semiconductor structures at various stages of the fabrication process. Specifically, FIGS. 2A (a)-2R (a) illustrate cross-sectional views of example semiconductor structures along the cut line AA′ of FIG. 1B, FIGS. 2A (b)-2R (b) illustrate cross-sectional views of the example semiconductor structures along the cut line BB′ of FIG. 1B, and FIGS. 2A (c)-2R (c) illustrate cross-sectional views of the example semiconductor structures along the cut line CC′ of FIG. 1B.

As shown in FIG. 2A, a semiconductor structure 200a is formed. The semiconductor structure 200a can have an array region 202 and a connection region 204 adjacent to the array region 202 (e.g., along the X direction). The array region 202 can be an example of the array region 102 of the semiconductor device 100 of FIGS. 1A-1D, and the connection region 204 can be an example of the connection region 104 of the semiconductor device 100. The semiconductor structure 200a includes a substrate 201 and a stack 205 of alternating sacrificial layers 205D and insulating layers 205B provided over the substrate 201. The stack 205 can extend across the array region 202 and the connection region 204. The sacrificial layers 205D and the insulating layers 205B can alternate in the vertical direction (e.g., the Z direction). The insulating layers 205B can include dielectric material, such as silicon oxide, silicon nitride, silicon oxynitride, or any combination thereof. In some implementations, the sacrificial layers 205D can include a dielectric material different from the dielectric material of the insulating layers 205B. For example, the insulating layers 205B can include silicon oxide, and the sacrificial layers 205D can include silicon nitride. In some implementations, the semiconductor structure 200a can further include a polysilicon layer 221 between the stack 205 and the substrate 201 along the vertical direction.

The semiconductor structure 200a can include channel holes 209 in the array region 202 and the connection region 204. The semiconductor structure 200a can further include gate line holes 211 arranged and spaced along a line extending in the X direction in the array region 202 and the connection region 204. The channel holes 209 and the gate line holes 211 can extend through the stack 205 and into the substrate 201 along the Z direction. In some implementations, the channel holes 209 and the gate line holes 211 can be formed by a same etching process. For example, the channel holes 209 and the gate line holes 211 can be formed by an etching process using one etching mask (not shown in FIG. 2A) applied on top of the semiconductor structure 200a. The etching mask can have patterns designed for these holes. The holes are formed by the etching process to extend through the sacrificial layers 205D and the insulating layer 205B of the stack 205 and down into the substrate 201.

As shown in FIG. 2A (c), the gate line holes 211 can include a first group of gate line holes 211a, a second group of gate line holes 211b, and a third group of gate line holes 211c. In some implementations, the gate line holes in each group can be consecutive. The first group of consecutive gate line holes 211a are between the second group of consecutive gate line holes 211b and the third group of consecutive gate line holes 211c (e.g., along the X direction). The first group of consecutive gate line holes 211a are adjacent to the second group of consecutive gate line holes 211b and the third group of consecutive gate line holes 211c (e.g., along the X direction).

FIG. 2B shows a semiconductor structure 200b including channel structures in the channel holes 209. The channel structures can be formed by filling components of a channel structure, such as a high-K layer, a block layer, a charge trapping layer, a tunneling layer, a channel layer, a core filler layer, and a channel contact into each of the channel holes 209. In some implementations, the channel structures in the array region 202 can be referred to as channel structures (e.g., channel structures 208), and the channel structures in the connection region 204 can be referred to as dummy channel structures (e.g., dummy channel structures 210). A filler material (e.g., polysilicon) can be filled into the gate line holes 211. In some implementations, before filling the filler material, protection structures (e.g., ploy oxidation) can be formed on bottoms (which can be in contact with the substrate 201) of the gate line holes 211 to protect the substrate 201. A dielectric layer (e.g., including silicon oxide) can be deposited on top of the channel holes 209 and the gate line holes 211.

As shown in FIG. 2C, a semiconductor structure 200c is formed by forming an opening in the dielectric layer on the top to expose the first group of consecutive gate line holes 211a and removing the filler material from the first group of consecutive gate line holes 211a.

As shown in FIG. 2D, a semiconductor structure 200d including an isolation trench 213a is formed. The isolation trench 213a can be formed by expanding the first group of consecutive gate line holes 211a in an etching process. For example, an etchant can be filled into the first group of consecutive gate line holes 211a to etch off a part of the stack 205 exposed by the first group of consecutive gate line holes 211a. The expanded first group of consecutive gate line holes 211a are connected with each other along the X direction and form the isolation trench 213a. As shown in FIG. 2D (b), each expanded gate line hole 211a can include a body portion 211a-1 above the substrate 201 and a bottom portion 211a-2 in the substrate 201. The bottom portion 211a-2 can be narrower than the body portion 211a-1 along the Y direction since during the etching process the substrate 201 may not be etched off by the etchant or may be etched off slower than the stack 205. For example, a size of a cross section of the bottom portion 211a-2 along the Y direction is smaller than a size of a cross section of the body portion 211a-1 along the Y direction.

FIG. 2E illustrates a semiconductor structure 200e including an isolation structure 215 in the isolation trench 213a. The isolation structure 215 can be formed by filling at least one isolating material into the isolation trench 213a. The isolating material can include a dielectric material and/or a filler material. In some implementations, as shown in FIGS. 2E (b) and 2E (c), the isolation structure 215 includes an inner structure 215a and an outer layer 215b surrounding the inner structure. The outer layer 215b can be formed, for example, by depositing a dielectric material (e.g., silicon oxide) on a bottom and an inner surface of the isolation trench 213a. The inner structure 215a can be formed, for example, by filling a filler material (e.g., polysilicon) into the isolation trench. In some implementations, as shown in FIGS. 2E (a)-2E (c), the outer layer 215b can extend to a top of the semiconductor structure 200e and form a top layer of the semiconductor structure 200c. In some implementations (not shown in FIG. 2E), the isolation structure 215 can be completely filled by a dielectric material (e.g., silicon oxide) and can be formed by filling the dielectric material into the isolation trench 213a. In other words, the isolation structure 215 can be a solid dielectric structure.

FIG. 2F illustrates a semiconductor structure 200f including a dielectric layer 217. The dielectric layer 217 can be formed by depositing a dielectric material (e.g., silicon oxide) on top of the semiconductor structure 200c. The dielectric layer 217 can cover a top of the inner structure 215a of the isolation structure 215.

FIG. 2G illustrates a semiconductor structure 200g including openings 219. The openings 219 extend from a top surface of semiconductor structure 200g and through the dielectric layer 217 along the Z direction. The openings 219 can expose the filler material in the second group of consecutive gate line holes 211b and the third group of consecutive gate line holes 211c.

As shown in a semiconductor structure 200h in FIG. 2H, the filler material in the second group of consecutive gate line holes 211b and the third group of consecutive gate line holes 211c can be removed.

FIG. 2I illustrates a semiconductor structure 200i including a gate line trench 223. The gate line trench 223 includes a segment 223a and a segment 223b. The gate line trench 223 can be formed by expanding the second group of consecutive gate line holes 211b and the third group of consecutive gate line holes 211c in a same etching process. The expanded second group of consecutive gate line holes 211b are connected with each other along the X direction and form the segment 223a of the gate line trench 223. The expanded third group of consecutive gate line holes 211c are connected with each other along the X direction and form the segment 223b of the gate line trench 223. In some implementations, the etching process can remove a portion of the isolation structure 215. For example, a portion (also referred to an end along the X direction) of the isolation structure 215 that overlaps with the segment 223a of the gate line trench 223 can be removed. Similarly, another portion (also referred to another end along the X direction) of the isolation structure 215 that overlaps with the segment 223b of the gate line trench 223 can also be removed. The removed portion of the isolation structure 215 can include at least a part of the outer layer 215b that extends along the Z direction. In some implementations, a top dielectric part (e.g., including the dielectric layer 217 and another part of the outer layer 215b of the isolation structure 215 that extends in the X-Y plane) of the semiconductor structure 200h can also be removed.

FIG. 2J illustrates a semiconductor structure 200j. The semiconductor structure 200j can be formed by removing some excess materials in the semiconductor structure 200i. In some implementations, a planarization process, such as chemical mechanical polishing (CMP), can be performed to make a top surface of the semiconductor structure 200j smooth and/or flat. In some implementations, a part of the inner structure 215a of the isolation structure 215 that is exposed to the segment 223a and the segment 223b of the gate line trench 223 can be removed (e.g., by an etching process). In other words, the inner structure 215a of the isolation structure 215 is shortened along the X direction. In some implementations, a part of the polysilicon layer 221 that is in the segment 223a and the segment 223b of the gate line trench 223 can be removed (e.g., by an etching process).

FIG. 2K illustrates a semiconductor structure 200k. The semiconductor structure 200k includes protection structures (e.g., ploy oxidation) formed on bottoms (which can be in contact with the substrate 201) of the segment 223a and the segment 223b of the gate line trench 223 (e.g., to protect the substrate 201) and on an outer surface of the inner structure 215a of the isolation structure 215 (e.g., to protect the inner structure 215a). As shown in FIGS. 2K (b) and 2K (c), the protection structure 225 in contact with the inner structure 215a along the X direction and a remaining portion of the outer layer 215b in contact with the inner structure 215a along the Y direction can be referred to as a new outer layer 227. In some implementations, the protection structure 225 includes a dielectric material (e.g., silicon oxide). Therefore, the semiconductor structure 200k includes a new isolation structure 206. The isolation structure 206 includes the inner structure 215a and the outer layer 227. In some implementations, the inner structure 215a includes a polysilicon material, and the outer layer 227 includes a dielectric material. In some other implementations (not shown in FIG. 2K), the inner structure 215a can also include a dielectric material (e.g., as described in the fabrication process of the isolation structure 215 with reference to FIG. 2E), and thus the isolation structure 206 can be a solid dielectric structure.

As shown in FIG. 2L, a semiconductor structure 200l can be formed by filling a filler material (e.g., polysilicon) into the segment 223a and the segment 223b of the gate line trench 223.

As shown in FIG. 2M, a semiconductor structure 200m including a dielectric layer 229 can be formed. The dielectric layer 229 can be formed by depositing a dielectric material (e.g., silicon oxide) on top of the semiconductor structure 200l. The dielectric layer 229 can cover the filler material in the segment 223a and the segment 223b of the gate line trench 223.

As shown in FIG. 2N, a semiconductor structure 200n is formed. The semiconductor structure 200n can include a gate line opening 228a and a gate line opening 228b in the dielectric layer 229. The gate line opening 228a can be on top of the segment 223a of the gate line trench 223 and can expose the filler material in the segment 223a of the gate line trench 223. The gate line opening 228b can be on top of the segment 223b of the gate line trench 223 and can expose the filler material in the segment 223b of the gate line trench 223.

As shown in FIG. 2O, a semiconductor structure 2000 can formed by removing the filler material in the segment 223a and the segment 223b of the gate line trench 223. The filler material can be removed, for example, by filling an etchant into the segment 223a and the segment 223b of the gate line trench 223 through the gate line openings 228a and 228b, respectively.

FIG. 2P illustrates a semiconductor structure 200p. The semiconductor structure 200p can be formed by replacing the sacrificial layers 205D in the stack 205 with conductive layers 205A. The sacrificial layers 205D can be removed by an etching process, which is performed, for example, by filling an etchant into the segment 223a and the segment 223b of the gate line trench 223 through the gate line openings 228a and 228b. The conductive layers 205A and the insulating layers 205B alternate with each other along the vertical direction (e.g., the Z direction). The conductive layers 205A can be formed by depositing at least one conductive material (e.g., W) into the segment 223a and the segment 223b of the gate line trench 223. In some implementations, before forming the conductive layers 205A, a high-K dielectric material (e.g., Al₂O₃) can be deposited on the surface of the insulating layers 205B to form liner layers 205C. The conductive layers 205A can be in contact with the liner layers 205C. In some implementations, each liner layer 205C can include an adhesive material (e.g., TiN) and a high-K dielectric material.

While FIGS. 2N and 2O illustrate a process of opening the segment 223a and the segment 223b of the gate line trench 223 by forming the gate line openings 228a and 228b and removing the filler material in the segment 223a and the segment 223b of the gate line trench 223, it is understood that the segment 223a and the segment 223b may not be opened at the same time. Due to the isolation structure 206, etchants can be filled into the segment 223a and the segment 223b of the gate line trench 223 in separate processes. In some implementations, such separate processes can result in more reliable conductive layers 205A, thereby improving the quality of the products and increasing the production yield. For example, the conductive layers 205A can be formed in the following processes. The segment 223b in the connection region 204 can be opened first (e.g., the filler material in the segment 223b is removed). A recess space in the connection region 204 can be formed by filling an etchant into the segment 223b of the gate line trench 223 to recess the sacrificial layers 205D in the connection region 204. The segment 223b of the gate line trench 223 and the recess space can be filled with a sacrificial material (e.g., carbon). The segment 223a in the array region 202 can be opened (e.g., the filler material in the segment 223a is removed). The sacrificial layers 205D in the array region 202 can be removed by filling the etchant into the segment 223a of the gate line trench 223. The sacrificial material in the segment 223b and the recess space can be removed. Then, the conductive layers 205A between the insulating layers 205B can be formed by depositing at least a conductive material through the segment 223a of the gate line trench 223.

FIG. 2Q illustrates a semiconductor structure 200q, which includes a gate line structure 212. The gate line structure 212 includes a segment 214a and a segment 214b formed by filling a semiconductor material (e.g., polysilicon) into the segment 223a and the segment 223b of the gate line trench 223, respectively. The semiconductor structure 200q can be an example of the semiconductor device 100 of FIGS. 1A-1D. The stack 205 can be similar to, or same as, the stack 105 of the semiconductor device 100. The gate line structure 212 can be similar to, or same as, the gate line structure 112 of the semiconductor device 100. The isolation structure 206 can be similar to, or same as, the isolation structure 106 of the semiconductor device 100.

FIG. 2R illustrates a semiconductor structure 200r, which can be another example of the semiconductor device 100 of FIGS. 1A-1D. The isolation structure 206 of the semiconductor structure 200r is a solid dielectric structure and can be formed as described above (e.g., with reference to FIGS. 2E and 2K).

In some implementations, in a later process, the substrate 201 and the polysilicon layer 221 in the semiconductor structure 200q or 200r can be removed. A part of each channel structure 208 that was in the substrate 301 can be removed. For example, a part of the channel structure 208's memory film that includes the ONO dielectrics (silicon Oxide-silicon Nitride-silicon Oxide) can be removed to expose the core filler layer of the channel structure. A part of the gate line structure 212 that was in the substrate 201 also can be removed to expose the semiconductor material of the gate line structure 212. A semiconductor layer (not shown) can be formed to connect the gate line structure 212 and the channel structures 208. In some implementations, the semiconductor layer can include any suitable semiconductor material (e.g., polysilicon) and can function as an array common source of memory strings (e.g., channel structures 208) of the semiconductor structure 200q or 200r.

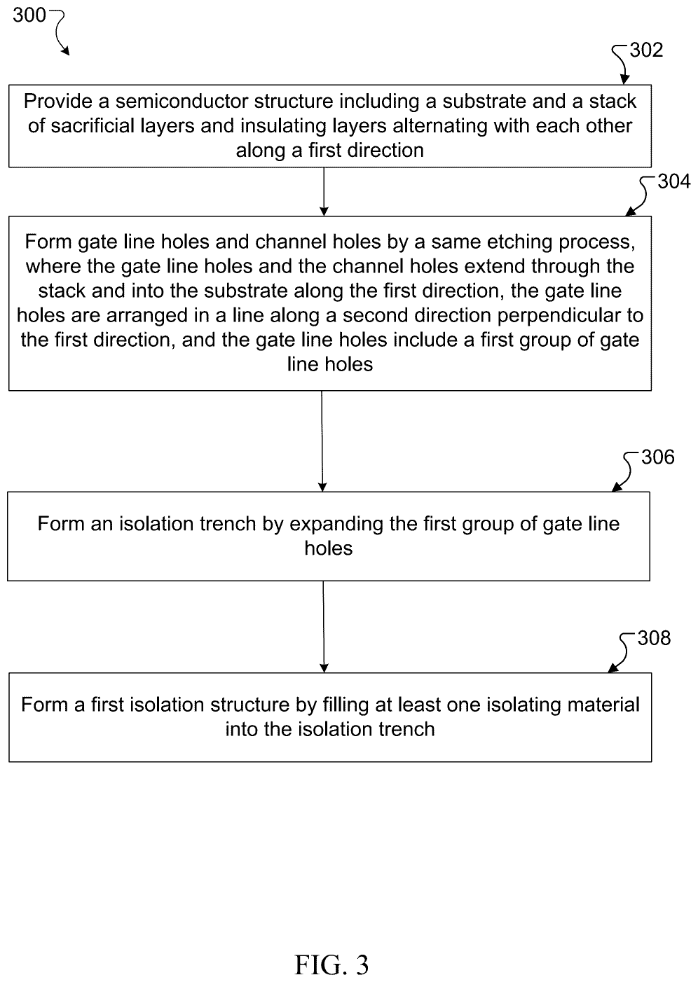

FIG. 3 illustrates a flow chart of an example process 300. The process 300 can be performed to form a semiconductor device (e.g., the semiconductor device 100 illustrated by FIGS. 1A-1D). The process 300 can be described in view of FIGS. 2A-2R. The process 300 can include one or more steps of the fabrication process of forming the semiconductor structures in FIGS. 2A-2R. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a semiconductor structure (e.g., the semiconductor structures 200a of FIG. 2A) is provided. The semiconductor structure can include a substrate (e.g., the substrate 201 of FIG. 2A) and a stack (e.g., the stack 205 of FIG. 2A) of sacrificial layers (e.g., the sacrificial layers 205D of FIG. 2A) and insulating layers (e.g., the insulating layers 205B of FIG. 2A) alternating with each other along a first direction (e.g., the Z direction).

At operation 304, gate line holes (e.g., the gate line holes 211 of FIG. 2A) and channel holes (e.g., the channel holes 209 of FIG. 2A) can be formed by a same etching process (e.g., as described with reference to FIG. 2A). The gate line holes and the channel holes can extend through the stack and into the substrate along the first direction. The gate line holes are arranged in a line along a second direction (e.g., the X direction) perpendicular to the first direction. The gate line holes include a first group of gate line holes (e.g., the gate line holes 211a of FIG. 2A).

At operation 306, an isolation trench (e.g., the isolation trench 213a of FIG. 2D) can be formed by expanding the first group of gate line holes (e.g., as described with reference to FIG. 2D).

At operation 308, a first isolation structure (e.g., the isolation structure 215 of FIG. 2E) can be formed by filling at least one isolating material (e.g., a dielectric material and/or a filler material as described with reference to FIG. 2E) into the isolation trench.

In some implementations, the gate line holes further include a second group of gate line holes (e.g., the gate line holes 211b of FIG. 2A) and a third group of gate line holes (e.g., the gate line holes 211c of FIG. 2A). The first group of gate line holes are between the second group of gate line holes and the third group of gate line holes. The first group of gate line holes are adjacent to the second group of gate line holes and the third group of gate line holes.

In some implementations, the isolation trench includes expanded gate line holes formed from the first group of gate line holes, and the expanded gate line holes are connected with each other along the second direction (e.g., as described with reference to FIG. 2D).

In some implementations, the first isolation structure includes a solid dielectric structure, and forming the first isolation structure includes filling a dielectric material (e.g., silicon oxide) into the isolation trench (e.g., as described with reference to FIG. 2E).

In some implementations, the first isolation structure includes an inner structure (e.g., the inner structure 215a of FIG. 2E) and an outer layer (e.g., the outer layer 215b of FIG. 2E) surrounding the inner structure. Forming the first isolation structure includes forming the outer layer by depositing a dielectric material (e.g., silicon oxide) on a bottom and an inner surface of the isolation trench and forming the inner structure by filling a filler material (e.g., polysilicon) into the isolation trench.

In some implementations, the process 300 further includes forming channel structures (e.g., the channel structures 208 and the dummy channel structures 210 of FIG. 2B) in the channel holes (e.g., as described with reference to FIG. 2B), filling the gate line holes with polysilicon (e.g., as described with reference to FIG. 2B), and removing the polysilicon in the second group of gate line holes and the third group of gate line holes (e.g., as described with reference to FIG. 2H).

In some implementations, the process 300 further includes forming a first segment (e.g., the segment 223a of FIG. 2I) of a gate line trench (e.g., the gate line trench 223 of FIG. 2I), a second segment (e.g., the segment 223b of FIG. 2I) of the gate line trench, and a second isolation structure (e.g., the isolation structure 206 of FIG. 2K) by expanding the second group of gate line holes and the third group of gate line holes (e.g., as described with reference to FIGS. 2I-2K).

In some implementations, the first segment of the gate line trench includes expanded gate line holes that are formed from the second group of gate line holes (e.g., the gate line holes 211b of FIG. 2A) and are connected with each other along the second direction. The second segment of the gate line trench includes expanded gate line holes that are formed from the third group of gate line holes (e.g., the gate line holes 211c of FIG. 2A) and are connected with each other along the second direction. The second isolation structure is formed by removing a first end of the first isolation structure and a second end of the first isolation structure. For example, the first end and the second end of the first isolation structures can be two ends or portions opposite to each other along the X direction as described with reference to FIG. 2I. The first end overlaps with the first segment of the gate line trench, and the second end overlaps with the second segment of the gate line trench.

In some implementations, the first segment of the gate line trench is in an array region (e.g., the array region 202 of FIGS. 2A-2R) of the semiconductor structure, the second isolation structure and the second segment of the gate line trench are in a connection region (e.g., the connection region 204 of FIGS. 2A-2R) of the semiconductor structure.

In some implementations, the process 300 further includes forming a recess space in the connection region by filling an etchant into the second segment of the gate line trench to recess the sacrificial layers (e.g., the sacrificial layers 205D of FIG. 2A) in the connection region. The process 300 further includes filling the second segment of the gate line trench and the recess space with carbon. The process 300 further includes removing the sacrificial layers in the array region by filling the etchant into the first segment of the gate line trench. The process 300 further includes removing the carbon in the connection region. The process 300 further includes forming conductive layers (e.g., the conductive layers 205A of FIG. 2P) between the insulating layers (e.g., the insulating layers 205B of FIG. 2P) by depositing at least a conductive material through the first segment of the gate line trench.

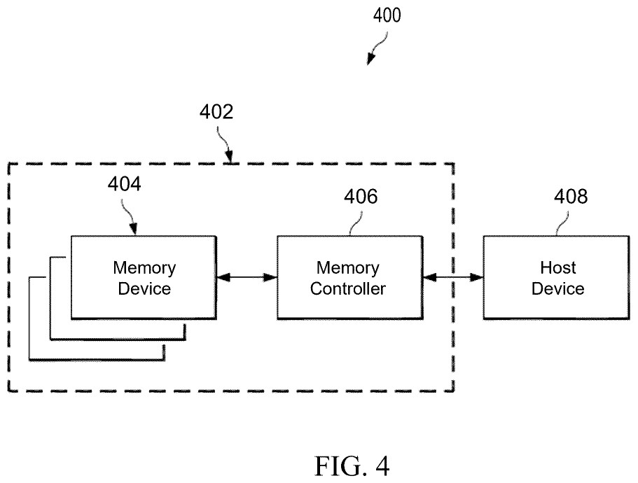

FIG. 4 illustrates a block diagram of an example system 400. The system 400 can have one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 4, the system 400 can include a host device 408 and a memory system 402 having one or more memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more memory devices 404.

A memory device 404 can be any memory device disclosed in the present disclosure, such as a memory device (e.g., a NAND Flash memory) as shown in FIGS. 1A-ID. Memory controller 406 (a.k.a., a controller circuit) is coupled to memory device 404 and host device 408. Consistent with implementations of the present disclosure, memory device 404 can include a plurality of conductive interconnections through a cover layer that are in contact with conductive pads in a conductive pad layer, and memory controller 406 can be coupled to memory device 404 through at least one of the plurality of conductive interconnections. Memory controller 406 is configured to control memory device 404. For example, memory controller 406 may be configured to operate a plurality of channel structures via word lines. Memory controller 406 can manage data stored in memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program (or write) operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−. 10%, .+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
an array region;
a connection region;
a stack of conductive layers and insulating layers alternating with each other along a first direction;
a gate line structure comprising at least a first segment and a second segment, wherein the gate line structure extends along a second direction perpendicular to the first direction; and
an isolation structure separating the first segment from the second segment, wherein a size of the isolation structure in a third direction is same as a size of the first segment in the third direction, the third direction being perpendicular to the first direction and the second direction.

2. The semiconductor device of claim 1, wherein a size of the isolation structure in the second direction is smaller than a size of the first segment in the second direction, the size of the isolation structure in the third direction is the same as a size of the second segment in the third direction.

3. The semiconductor device of claim 2, wherein the isolation structure extends through the stack along the first direction, the isolation structure is between dummy channel structures along the third direction, a part of at least one insulating layer of the stack separates the isolation structure and the dummy channel structures from each other along the third direction, the gate line structure extends through the stack along the first direction, and the gate line structure extends into the array region and the connection region along the second direction.

4. The semiconductor device of claim 1, wherein the isolation structure comprises a first sidewall in contact with the first segment and a second sidewall in contact with the second segment, the first sidewall and the second sidewall each have a concave surface extending along the first direction, the isolation structure comprises a third sidewall and a fourth sidewall in contact with the stack along the third direction, and the third sidewall and the fourth sidewall each comprise a series of curved portions.

5. The semiconductor device of claim 1, wherein a bottom of the isolation structure comprises a series of bases arranged in a line along the second direction, a size of a first cross section of each base of the series of bases is greater than a size of a second cross section of the base, the first cross section and the second cross section are perpendicular to the first direction, and the first cross section is closer to the stack than the second cross section along the first direction.

6. The semiconductor device of claim 1, wherein the first segment is in the array region, the second segment and the isolation structure are in the connection region.

7. The semiconductor device of claim 1, wherein the first segment, the second segment, and the isolation structure are in the array region.

8. The semiconductor device of claim 1, wherein the isolation structure comprises a dielectric material.

9. The semiconductor device of claim 1, wherein the isolation structure comprises an inner structure and an outer layer surrounding the inner structure, and the inner structure and the outer layer comprise different materials.

10. A method, comprising:
providing a semiconductor structure comprising a substrate and a stack of sacrificial layers and insulating layers alternating with each other along a first direction;
forming gate line holes and channel holes by a same etching process, wherein the gate line holes and the channel holes extend through the stack and into the substrate along the first direction, the gate line holes are arranged in a line along a second direction perpendicular to the first direction, and the gate line holes comprise a first group of gate line holes;
forming an isolation trench by expanding the first group of gate line holes; and
forming a first isolation structure by filling at least one isolating material into the isolation trench.

11. The method of claim 10, wherein the gate line holes further comprise a second group of gate line holes and a third group of gate line holes, the first group of gate line holes are between the second group of gate line holes and the third group of gate line holes, and the first group of gate line holes are adjacent to the second group of gate line holes and the third group of gate line holes.

12. The method of claim 10, wherein the isolation trench comprises expanded gate line holes formed from the first group of gate line holes, and the expanded gate line holes are connected with each other along the second direction.

13. The method of claim 10, wherein the first isolation structure comprises a solid dielectric structure, and forming the first isolation structure comprises:
filling a dielectric material into the isolation trench.

14. The method of claim 10, wherein the first isolation structure comprises an inner structure and an outer layer surrounding the inner structure, and forming the first isolation structure comprises:
forming the outer layer by depositing a dielectric material on a bottom and an inner surface of the isolation trench; and
forming the inner structure by filling a filler material into the isolation trench.

15. The method of claim 11, further comprising:
forming channel structures in the channel holes;
filling the gate line holes with polysilicon; and
removing the polysilicon in the second group of gate line holes and the third group of gate line holes.

16. The method of claim 15, further comprising:
forming a first segment of a gate line trench, a second segment of the gate line trench, and a second isolation structure by expanding the second group of gate line holes and the third group of gate line holes.

17. The method of claim 16, wherein:
the first segment of the gate line trench comprises expanded gate line holes that are formed from the second group of gate line holes and are connected with each other along the second direction;
the second segment of the gate line trench comprises expanded gate line holes that are formed from the third group of gate line holes and are connected with each other along the second direction; and
the second isolation structure is formed by removing a first end of the first isolation structure and a second end of the first isolation structure, wherein the first end overlaps with the first segment of the gate line trench, and the second end overlaps with the second segment of the gate line trench.

18. The method of claim 16, wherein the first segment of the gate line trench is in an array region of the semiconductor structure, and the second isolation structure and the second segment of the gate line trench are in a connection region of the semiconductor structure.

19. The method of claim 18, further comprising:
forming a recess space in the connection region by filling an etchant into the second segment of the gate line trench to recess the sacrificial layers in the connection region;
filling the second segment of the gate line trench and the recess space with carbon;
removing the sacrificial layers in the array region by filling the etchant into the first segment of the gate line trench;
removing the carbon in the connection region; and
forming conductive layers between the insulating layers by depositing at least a conductive material through the first segment of the gate line trench.

20. A memory system, comprising:
a memory device; and
a memory controller coupled to the memory device and configured to control the memory device,
wherein the memory device comprises:
an array region;
a connection region;
a stack of conductive layers and insulating layers alternating with each other along a first direction;
a gate line structure comprising at least a first segment and a second segment, wherein the gate line structure extends along a second direction perpendicular to the first direction; and
an isolation structure separating the first segment from the second segment, wherein a size of the isolation structure in a third direction is same as a size of the first segment in the third direction, the third direction being perpendicular to the first direction and the second direction.
